(19) United States
(12) Patent Application Publication
(10) Pub. No.: US 2008/0142877 A1
(43) Pub. Date: Jun. 19, 2008

(54) Nonvolatile semiconductor memory

(75) Inventors: Takahisa Hayashi, Tokyo (JP); Takashi Yuda, Kanagawa (JP)

Correspondence Address: JUNICHI MIMURA;OKI AMERICA INC., 1101 14TH STREET, N.W., SUITE 555, WASHINGTON, DC, 20005, US

(73) Assignee: Oki Electric Industry Co., Ltd.

(21) Appl. No.: 11/987,169

(22) Filed: Nov. 28, 2007

(30) Foreign Application Priority Data
Dec. 15, 2006 (JP) 2006-338728

(51) Int. Cl. H01L 29/792

(52) U.S. Cl. 257/324; 257/E29.309

(57) ABSTRACT

A nonvolatile semiconductor memory having an LDD structure includes a control gate located above a channel region, insulating layers formed on the both side surface of the control gate, and I-letter shaped charge-storage layers formed on the insulating layers wherein a bottom surface of the each charge-storage layer are located above the LDD.

### CROSS-REFERENCE TO RELATED APPLICATION

This application claims the priority benefit of Japanese Patent Application No. 2006-338728, filed Dec. 15, 2006, the entire disclosure of which is incorporated herein by reference.

### BACKGROUND OF THE INVENTION

1. Field of the Invention

The invention relates to a rewritable nonvolatile semiconductor memory, specifically, relates to a flash memory having a MONOS (Metal-Oxide-Nitride-Oxide-Silicon) structure.

2. Description of the Related Art

One of the most well-known rewritable nonvolatile semiconductor memories is a flash memory having a MONOS structure. Such a flash memory having the MONOS is disclosed in the following references.

Japanese Patent Publication Reference 2006-19373A

Japanese Patent Publication Reference 2006-19680A

Japanese Patent Publication Reference 2006-24680A

A flash memory having a MONOS structure in the related art is illustrated in FIG. 4. As shown in FIG. 4, the flash memory 400 includes a P-type silicon substrate 401, an insulating layer 403 formed on the substrate 401 at its channel region 402 and a gate electrode 404 acting as a control electrode formed on the insulating layer 403. On the surface of the substrate 401, highly doped N-type diffusion layers 405 and 406 are formed to sandwich the channel region 402, and lightly doped N-type diffusion layers 407 and 408 are formed at both boundaries between the channel region 402 and the highly doped N-type diffusion layers 405 and 406. At the side surface of the gate electrode 404 (the sides at which the lightly doped N-type diffusion layers 407 and 408 are formed), insulating layers 409 are formed. L-shaped charge-storage layers 410 and 411 are formed directly on the insulating layers 403 and 409. As illustrated in FIG. 4, each of the L-shaped charge-storage layers 410 and 411 are completely covered an area located above the region where one of the lightly doped N-type diffusion layers 407 and 408 is formed, and extends above another area located above a part of the region where one of the highly doped N-type diffusion layers 405 and 406 is formed.

FIG. 5 shows a conceptual cross-sectional view of the flash memory 400 to explain the principal for writing data therein. As shown in FIG. 5, when data is written in the charge-storage layer 410, which is located in the right side, the highly doped N-type diffusion layer 405 located at the right side acts as a drain while the highly doped N-type diffusion layer 406 located at the left side acts as a source. In order to write the data, while the electric potential of the source 406 is set at 0 volt, a high voltage is applied to the gate electrode 404 and the drain 405. In the flash memory 400 illustrated in FIG. 5, 10 volt is applied to the gate electrode 404, and the 5 volt is applied to the drain 405. Under the condition described above, hot carriers are generated, and electrons are injected into the charge-storage layer 410.

On the other hand, when data is written in the charge-storage layer 411, which is located in the left side, while the electric potential of the highly doped diffusion layer 405 is set at 0 volt, a high voltage is applied to the gate electrode 404 and the highly doped diffusion layer 406.

FIG. 6A shows a conceptual cross-sectional view of the flash memory 400 to explain the principal for read-out data stored in the charge-storage layers 410 and 411. FIG. 6B is a characteristic graph to show a relationship of a drain current value and a memory value, which indicates a condition whether or not the data is stored, at the time for reading-out the data. In FIG. 6B, the gate voltage is measured along the horizontal axis and the drain current is measured along the vertical axis. As shown in FIG. 6A, when data is read-out from the charge-storage layer 410, which is located in the right side, the highly doped N-type diffusion layer 405 located at the right side acts as a source while the highly doped N-type diffusion layer 406 located at the left side acts as a drain.

According to the read-out operation shown in FIG. 6A, while the electric potential of the highly doped diffusion layer 405 acting as the source is set at 0 volt, the 3-volt gate voltage is applied to the gate electrode 404 and the 2-volt drain voltage is applied to the highly doped diffusion layer 406 acting as the drain. Under this condition, a channel, which is an inversion layer 601, is produced under the gate electrode 404 in the substrate 401. As a result, the electrons flowed out from the source 405 are transferred to the drain 406 so that the drain current is generated.

In the case that the electric charges are stored in the charge-storage layer 410, which is located at the source side, the leakage of the electrons from the source is restricted by the electric field created by the electric charges. Thus, the drain current in the case that the electric charges are stored in the charge-storage layer 410, which is located at the source side, is smaller than that in the case that the electric charges are not stored therein as referred in FIG. 6B.

On the other hand, direct-under the charge-storage layer 411, which is located at the drain side (left side), a depletion layer 602 is generated by the drain voltage. For this reason, the inversion layer 602 includes a pinch-off point near the charge-storage layer 411, which is located at the drain side. Thus, the influence that the existence/non-existence of the charge in the charge-storage layer 411, which is located at the drain side, gives the drain current value is small than that that the existence/non-existence of the charge in the charge-storage layer 410, which is located at the source side.

For this reason, by comparing the drain current value to the predetermined threshold, it can be judged whether or not the charge-storage layer 410, which is located at the source side, stores the electric charges. In other words, it can be judged whether a certain memory cell stores the data or not by measuring the drain current value and by comparing it with the predetermined threshold.

On the other hand, when data is read-out from the charge-storage layer 411, which is located in the left side, while the electric potential of the highly doped diffusion layer 406 is set at 0 volt, a high voltage is applied to the gate electrode 404 and the highly doped diffusion layer 405.

As described above, although the influence that the existence/non-existence of the charge in the charge-storage layer 411, which is located at the drain side, gives the drain current value is small than that that the existence/non-existence of the charge in the charge-storage layer 410, which is located at the source side, such the influence cannot go ignored, completely, because the existence/non-existence of the charge in the charge-storage layer 411, that is the memory value, fluctuates the drain current value at a constant rate.

FIG. 7 is a characteristic graph to show a relationship of a drain current vale and a memory value at the time for reading-out the data in order to compare two conditions that the electric charges are and are not stored in a charge storage layer formed at the drain side while the electric charges are stored in a charge storage layer formed at the source side. In FIG. 7, the gate voltage of the flash memory 400 is measured along the horizontal axis and the drain current is measured along the vertical axis.

As shown in FIG. 7, a slope of a graph line A indicating the condition that the electric charges are stored in the charge-storage layer located at the drain side while the electric charges are also stored in the charge-storage layer located at the source side becomes smaller than that of a graph line B indicating the condition that the electric charges are not stored in the charge-storage layer located at the drain side while the electric charges are also stored in the charge-storage layer located at the source side. Thus, compared with the condition that the electric charges are not stored in the charge-storage layer located at the drain side, when the electric charges are stored in the charge-storage layer located at the drain side, the difference of the drain current value, which is changed on the condition of the memory value of the charge-storage layer located at the source side, is smaller. As a result, the reading margin for the memory value is reduced.

### SUMMARY OF THE INVENTION

An objective of the invention is to solve the above-described problem and to provide a nonvolatile semiconductor memory whose influence that the memory value in the charge-storage layer located at the drain side gives the drain current is small, that is a nonvolatile semiconductor memory having a large reading margin.

The objective is achieved by a nonvolatile semiconductor memory of an LDD (Lightly Doped Drain) structure including a control gate located above a channel region, insulating layers formed on the both side surface of the control gate, and I-letter shaped charge-storage layers formed on the insulating layers wherein a bottom surface of the each charge-storage layer are located above the LDD.

### BRIEF DESCRIPTION OF THE DRAWINGS

The invention will be more particularly described with reference to the accompanying drawings, in which:

FIG. 1A is a cross-sectional view of a nonvolatile semiconductor memory, according to a preferred embodiment;

FIG. 1B is an enlarged cross-sectional view at an alternative first charge-storage layer;

FIG. 2A is a conceptual cross-sectional view of the flash memory shown in FIG. 1A to explain the principal for reading-out data; and

FIG. 2B is an enlarged cress-section view in an area A illustrated in FIG. 2A;

FIG. 3 is a characteristic graph to show a relationship of a drain current vale and a memory value at the time for reading out data;

FIG. 4 is a cross-sectional view of a nonvolatile semiconductor memory in the related art;

FIG. 5 is a conceptual cross-sectional view of the flash memory shown in FIG. 4 to explain the principal for writing data;

FIG. 6A is a conceptual cross-sectional view of the flash memory shown in FIG. 4 to explain the principal for reading-out data;

FIG. 6B is a characteristic graph to show a relationship of a drain current vale and a memory value at the time for reading-out the data in order to compare two conditions that the electric charges are and are not stored in a charge storage layer formed at the source side; and

FIG. 7 is a characteristic graph to show a relationship of a drain current vale and a memory value at the time for reading-out the data in order to compare two conditions that the electric charges are and are not stored in a charge storage layer formed at the drain side while the electric charges are stored in a charge storage layer formed at the source side.

### DETAILED DESCRIPTION OF THE PREFERRED EMBODIMENTS

The preferred embodiment of the invention is explained together with drawings as follows. In each drawing, the same reference numbers designate the same or similar components.

### The Preferred Embodiment

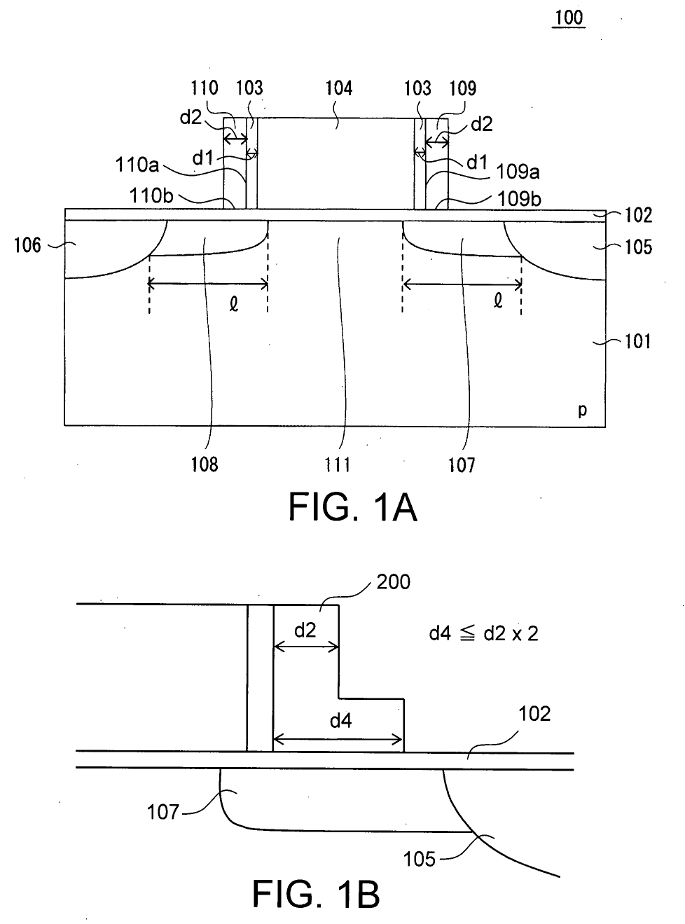

FIG. 1A is a cross-sectional view of a nonvolatile semiconductor memory, such as a flash memory 100, according to a preferred embodiment. As shown in FIG. 1A, the flash memory 100 includes a P-type semiconductor substrate 101, a first and a second insulating layers 102 and 103, a gate electrode 104 acting as a control electrode, a first and a second N-type highly doped diffusion layers 105 and 106, a first and a second N-type lightly doped diffusion layers 107 and 108 and a first and a second charge-storage layers 109 and 110.

The P-type semiconductor substrate 101 is formed of P-type silicon or formed of a semiconductor substrate having a P-type well layer.

The first insulating layer 102 is formed on the top surface of the P-type semiconductor substrate 101. The first insulating layer 102 acts not only as a gate insulating layer, but also as a layer for insulating the first and the second N-type lightly doped diffusion layers 107 and 108 from the first and the second charge-storage layers 109 and 110.

The second insulating layers 103 are formed on the gate electrode 104 at its both sides, and acts as a layer for insulating the gate electrode 104 from the first and the second charge-storage layers 109 and 110. The thickness (d1) of the second insulating layers 103 is preferably set in the range between 4 nm and 10 nm. When the second insulating layers 103 having its thickness (d1) less than 4 nm is used, a tunnel current may flow between the gate electrode 104 and the first or the second charge-storage layer 109 or 110. As a result, the electric charges stored in the first or the second charge-storage layer 109 or 110 may be flowed out. On the other hand, when the second insulating layers 103 having its thickness (d1) more than 10 nm is used, the cost for manufacturing the flash memory increases.

The gate electrode 104 is formed on the substrate 101 at a channel region 111 via the first insulating layer 102. The first and the second lightly doped diffusion layers 107 and 108, which sandwiches the channel region 111, are formed at the top surface of the substrate 101.

The first lightly doped diffusion layer 107 having the width (l) of 30 nm is formed at the boundary area formed between the channel region 111 and the first highly doped diffusion layer 105. The second lightly doped diffusion layer 108 having the width of 30 nm is formed at the boundary area formed between the channel region 111 and the second highly doped diffusion layer 106.

The first charge-storage layer 109 stores electrons provided from the second highly doped diffusion layer 106 via the first lightly doped diffusion layer 107. The first charge-storage layer 109 is formed on the side surface of the gate electrode 104 via the second insulating layer 103, and is formed on the substrate 101 via the first insulating layer 102. Thus, the first charge-storage layer 109 includes the side surface 109a contacting to the second insulating layer 103, and the bottom surface 109b contacting the first insulating layer 102. Both edges of the bottom surface 109b of the first charge-storage layer 109 are located above the first lightly doped diffusion layer 107. Thus, the first charge-storage layer 109 is not extended above the first highly doped diffusion layer 105. The first charge-storage layer 109 at its cross sectional view is I-letter-shaped.

The second charge-storage layer 110 stores electrons provided from the first highly doped diffusion layer 105 via the second lightly doped diffusion layer 108. The second charge-storage layer 110 is formed on the side surface of the gate electrode 104 via the second insulating layer 103, and is formed on the substrate 101 via the first insulating layer 102. Thus, the second charge-storage layer 110 includes the side surface 110a contacting to the second insulating layer 103, and the bottom surface 110b contacting the first insulating layer 102. Both edges of the bottom surface 110b of the first charge-storage layer 110 are located above the second lightly doped diffusion layer 108. Thus, the second charge-storage layer 110 is not extended above the second highly doped diffusion layer 106. The second charge-storage layer 110 at its cross sectional view is I-letter-shaped.

The thickness (d2) of the first charge-storage layer 109 is preferably set in the range between 4 nm and 15 nm. In the case that the first charge-storage layer 109 having its thickness (d2) less than 4 nm is used, when the first charge-storage layer 109 acts as a charge-storage layer located at the source side, the control effect for the drain current may be insufficient. On the other hand, in the case that the first charge-storage layer 109 having its thickness (d2) more than 15 nm, which means more than half of the length of the first lightly doped diffusion layer 107, is used, when the first charge-storage layer 109 acts as a charge-storage layer located at the drain side, the influence to the drain current cannot be ignored as will hereinafter be described in detail. However, even if the thickness (d2) of the first charge-storage layer 109 exceeds 15 nm, the influence to the drain current can be reduced, provided the first charge-storage layer 109 does not reach onto the first highly doped diffusion layer 105. The thickness (d2) of the second charge-storage layer 110 is preferably set in the range between 4 nm and 15 nm for the same reasons described above.

In the preferred embodiment, although either the first or the second charge-storage layer 109 or 110 at its cross sectional view is I-letter-shaped, an alternative L-shaped charge-storage layer 200 may be used, provided each of the first and the second charge-storage layers 200 does not reach onto one of the first and second highly doped diffusion layers 105 and 106, as shown in FIG. 1B. When the L-letter-shaped charge-storage layer 200 is used, it is preferable that the thickness (d4) of the L-letter-shaped charge-storage layer 200 in an area where the L-letter-shaped charge-storage layer 200 contacts the first lightly doped diffusion layer 107 via the first insulating layer 102 is equal to or less than double of the thickness (d2) of the L-letter-shaped charge-storage layer 200 in another area where the L-letter-shaped charge-storage layer 200 does not contact the first lightly doped diffusion layer 107 via the first insulating layer 102, in order to become fully effective.

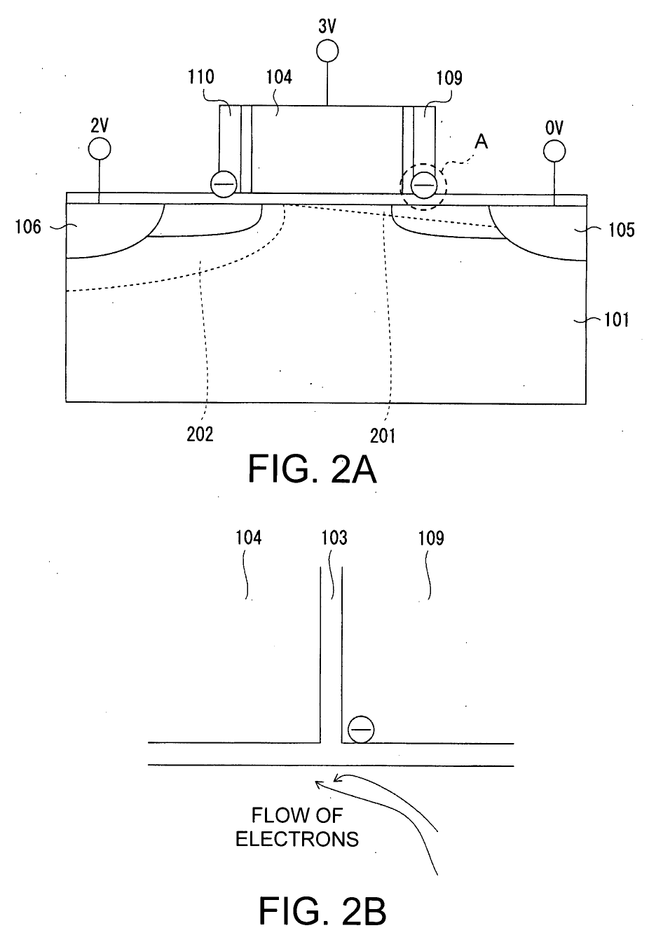

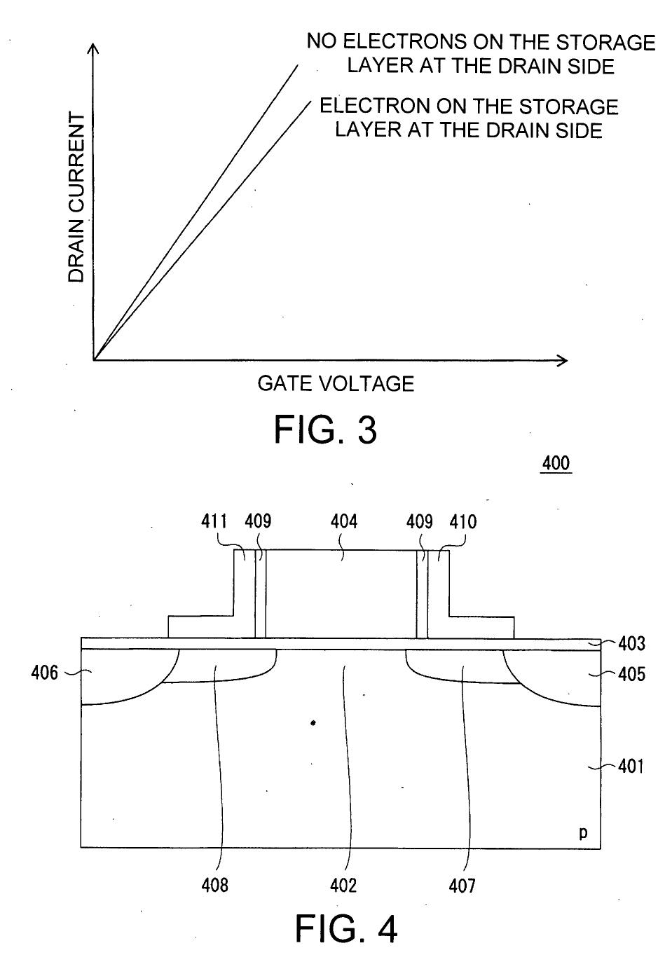

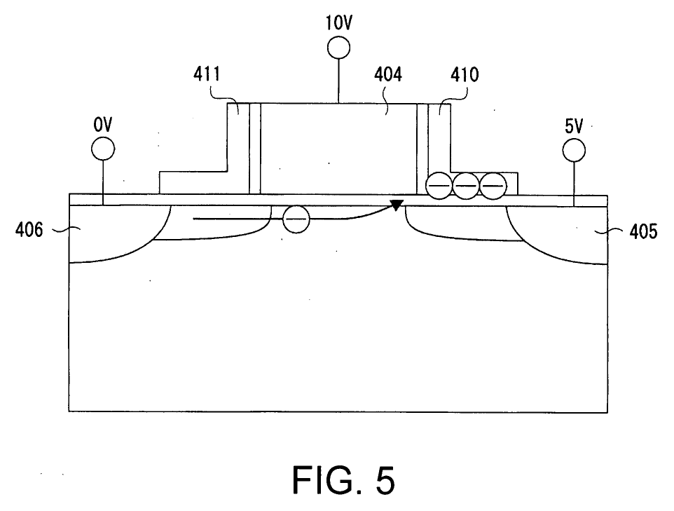

The principal for reading-out data in the flash memory 100 according to the preferred embodiment is explained as follows with reference to FIGS. 2A, 2B and 3. FIG. 2A is a conceptual cross-sectional view of the flash memory shown in FIG. 1A to explain the principal for reading-out data, and FIG. 2B is an enlarged cress-section view in an area A illustrated in FIG. 2A. FIG. 3 is a characteristic graph to show a relationship of a drain current vale and a memory value at the time for reading out the data. In FIG. 3, the gate voltage is measured along the horizontal axis and the drain current is measured along the vertical axis.

As shown in FIG. 2A, when the data is read-out from the charge-storage layer 109, which is located in the right side, the first highly doped N-type diffusion layer 105 located at the right side acts as a source while the second highly doped N-type diffusion layer 106 located at the left side acts as a drain.

According to the read-out operation shown in FIG. 2A, while the electric potential of the first highly doped diffusion layer 105 acting as the source is set at 0 volt, the 3-volt gate voltage is applied to the gate electrode 104 and the 2-volt drain voltage is applied to the second highly doped diffusion layer 106 acting as the drain. Under this condition, a channel, which is an inversion layer 201, is produced under the gate electrode 104 in the substrate 101. As a result, the electrons are flowed out from the source 105.

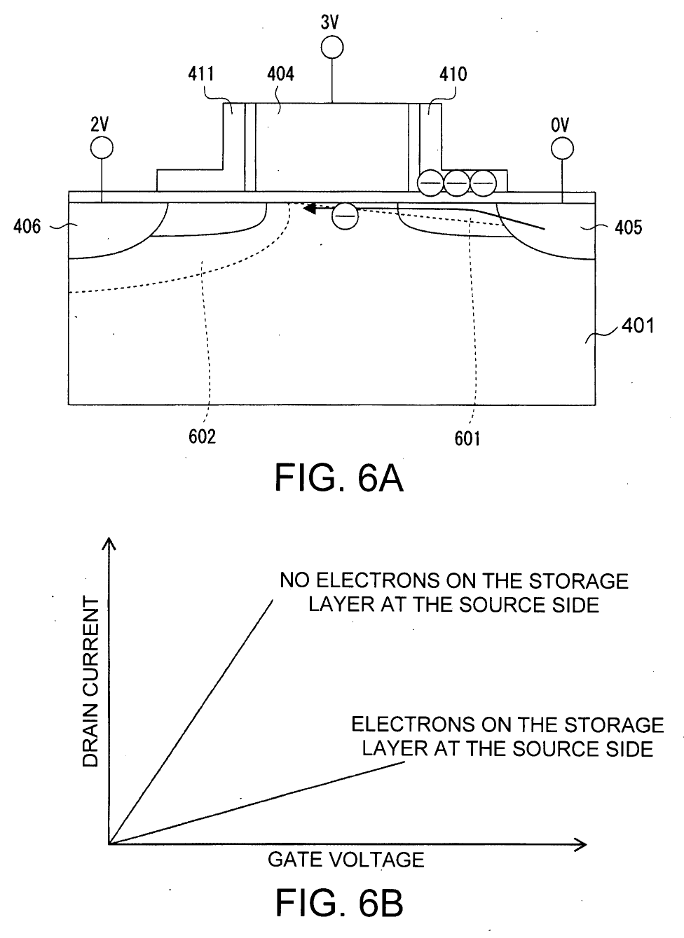

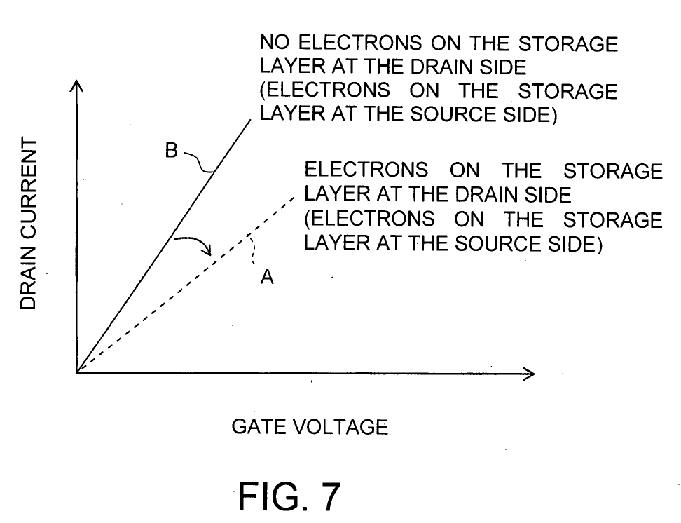

As shown in FIG. 2B, the electrons flowed out from the source 105, which are gravitated by the electric field generated by the gate electrode 104, gather around an area adjacent to the source side edge of the gate electrode 104. Thus, the electric field component generated by the charges, which are gathered around the area adjacent to the source side edge of the gate electrode 104, among the electric fields generated by the first charge-storage layer 109 contributes to control the drain current value. For this reason, when the first charge-storage layer 109, which is located as the source side, is I-letter-shaped, the influence that the condition whether or not the electric charge is stored in the first charge-storage layer 109 gives the drain current vale is not deteriorated. Thus, the graph lines, which are same as or similar to these illustrated in FIG. 6, can be expected even if the first charge-storage layer 109 is I-letter-shaped.

On the other hand, at the drain side, since a depletion layer 202 is produced because an inversion layer 201 includes a pinch-off point near the second charge-storage layer 110, the electrons flowed out from the source 105 is transferred as diffusion current. The diffusion current is influenced by the electric field of the entire second charge-storage layer 110 located at the drain side. For this reason, thinner the thickness (d2) of the second charge-storage layer 110 located at the drain side is, smaller the influence that the existence/non-existence of the charge in the second charge-storage layer 110, which is located at the drain side, gives the drain current value is. As shown in FIG. 3, since the thickness (d2) of the second charge-storage layer 110 located at the drain side is shorter so that the second lightly doped diffusion layer 108 is not completely covered with the second charge-storage layer 110 via the first insulating layer 102, the condition of the memory value at the first charge-storage layer 109 can be detected by the drain current value at the time of the read out the data regardless the condition whether or not the electric charge is stored in the second charge-storage layer 110, which is located at the drain side because the influence that the existence/non-existence of the charge in the second charge-storage layer 110, which is located at the drain side, gives the drain current value is very small.

In sake of brevity, the explanation of the principal for writhing data is omitted here because it is the same as that of the flash memory 400 described in the related art.

According to the flash memory 100 of the preferred embodiment, the first and the second charge-storage layers 109 and 110 are formed on the side surfaces of the gate electrode 104 via the second insulating layer 103, and are not extended to the first and the second highly doped diffusion layers 105, 106, respectively, the influence that the memory value in the charge-storage layer located at the drain side gives a drain current value is small. Thus, the flash memory having a large reading margin for the memory value can be presented.

While the invention has been described with reference to illustrative embodiments, this description is not intended to be construed in a limiting sense. Thus, shapes, size and physical relationship of each component are roughly illustrated so the scope of the invention should not be construed to be limited to them. Further, to clarify the components of the invention, hatching is partially omitted in the cross-sectional views. Moreover, the numerical description in the embodiment described above is one of the preferred examples in the preferred embodiment so that the scope of the invention should not be construed to limit to them. For example, while the N-channel type flash memory is used in the preferred embodiment, the invention can be used to a P-channel type flash memory.

Various other modifications of the illustrated embodiment will be apparent to those skilled in the art on reference to this description. Therefore, the appended claims are intended to cover any such modifications or embodiments as fall within the true scope of the invention.

What I claim is:

1. A nonvolatile semiconductor memory, comprising:
a semiconductor substrate, which has a top surface and a bottom surface and includes a channel region at the top surface, including a first and a second highly doped diffusion layers formed at the top surface by which the channel region is sandwiched, and a first and a second lightly doped diffusion layers, each of which is formed at a boundary region between the one of the first and the second highly doped diffusion layers and the channel region;
a first insulating layer formed on the top surface of the semiconductor substrate;
a control electrode having side surfaces formed on the semiconductor substrate at the channel region via the first insulating layer;
second insulating layers, each of which is formed on the one of the side surfaces of the control gate; and
a first and a second charge-storage layers, the first charge-storage layer, which includes a side surface and a bottom surface, storing electric charges supplied from the second highly doped diffusion layer via the first lightly doped diffusion layer and the second charge-storage layer, which includes a side surface and a bottom surface, storing electric charges supplied from the first highly doped diffusion layer via the second lightly doped diffusion layer,
wherein the side surface and the bottom surface of the first charge-storage layer contacts one of the second insulating layers and the first insulating layer, respectively, and the first charge-storage layer is not extend onto the first highly doped diffusion layer so that its both edges of the bottom surface are located above the first lightly doped diffusion layer, and wherein the side surface and the bottom surface of the second charge-storage layer contacts the other of the second insulating layers and the first insulating layer, respectively, and the second charge-storage layer is not extend onto the second highly doped diffusion layer so that its both edges of the bottom surface are located above the second lightly doped diffusion layer.

2. A nonvolatile semiconductor memory as claimed in claim 1, wherein each of the first and the second charge-storage layers at its cross sectional view is I-letter-shaped.

3. A nonvolatile semiconductor memory as claimed in claim 1, wherein the first charge-storage layer at its cross sectional view is L-letter-shaped, and wherein the thickness of the first charge-storage layer in an area where the first charge-storage layer contacts the first lightly doped diffusion layer via the first insulating layer is equal to or less than double of the thickness of the first charge-storage layer in another area where the first charge-storage layer does not contact the first lightly doped diffusion layer via the first insulating layer.

4. A nonvolatile semiconductor memory as claimed in claim 2, wherein each second insulating layer has a thickness in the range between 4 nm and 10 nm.

5. A nonvolatile semiconductor memory as claimed in claim 3, wherein each second insulating layer has a thickness in the range between 4 nm and 10 nm.

6. A nonvolatile semiconductor memory as claimed in claim 3, wherein the first lightly doped diffusion layer has a length of around 30 nm in the channel direction.

7. A nonvolatile semiconductor memory as claimed in claim 2, wherein each of the first and the second charge-storage layers has a thickness in the range between 4 nm and 15 nm.

9. A nonvolatile semiconductor memory as claimed in claim 3, wherein the first charge-storage layers has a thickness in the range between 4 nm and 15 nm.
